(19) United States
(12) Patent Application Publication
(10) Pub. No.: US 2010/0187682 A1
(43) Pub. Date: Jul. 29, 2010

(54) ELECTRONIC PACKAGE AND METHOD OF ASSEMBLING THE SAME

(76) Inventors: Damaruganath Pinjala, Singapore (SG); Navas Khan Oratti Kalandar, Singapore (SG); Hengyun Zhang, Singapore (SG); Ebin Liao, Singapore (SG); Qingxin Zhang, Singapore (SG); Nagarajan Ranganathan, Singapore (SG); Vaidyanathan Kripesh, Singapore (SG)

Correspondence Address: Altera Law Group, LLC, 220 S 6 St Suite 1700, Minneapolis, MN, 55402, US

(21) Appl. No.: 12/442,192

(22) PCT Filed: Sep. 21, 2007
(86) PCT No.: PCT/SG07/00320

§ 371 Date: Oct. 26, 2009

Related U.S. Application Data
(60) Provisional application No. 60/826,481, filed on Sep. 21, 2006.

(51) Int. Cl. H01L 23/46; H01L 21/02

(52) U.S. Cl. 257/713; 257/712; 438/122; 257/E21.002; 257/E23.097

(57) ABSTRACT

An electronic package (200) comprises a substrate (201), a first carrier layer arrangement (211) adapted to dissipate heat from at least one chip (217) mounted thereon, and a heat exchanger (221) mounted on the first carrier layer arrangement. The first carrier layer arrangement comprises at least one internal microchannel (213), which is fluidically interconnected with the heat exchanger (221) though an inlet (215) and an outlet (219). The heat exchange further comprises a pump (223) controlling fluid flow through the microchannel (213). The package may further comprise a stack of carrier layer arrangements (211), each of which may have one or more chips (217) mounted thereon.

### CROSS-REFERENCE TO RELATED APPLICATION

This application claims the benefit of priority of U.S. provisional application 60/826,481 filed on 21 Sep. 2006, the entire content of which is incorporated here by reference for all purposes.

### FIELD OF THE INVENTION

Embodiments of the present invention relate generally to an electronic package, in particular an electronic package with integrated cooling structure, and a method for assembling the same.

### BACKGROUND

A System in a Package and System on a Package (SiP/SoP) technologies are considered to be the fourth wave of packaging innovation. Reduction of interconnect length and delays are some of the key issues addressed by these technologies. Three-dimensional (3-D) packaging is the preferred technology for many SiP/SoP applications because of the advantages of smaller size, shorter signal routing, and reduced wiring density at the second level. 3-D stacked packaging is achieved by different techniques, such as die level stacking, package level stacking, and wafer level stacking.

However, current 3-D package applications are limited to die level and package level stacking for lower power applications, such as memory devices, base band, and logic devices. High thermal resistance of the 3-D package is a barrier for integrating high power chips in 3-D stacked configuration. Projected power dissipations for cost performance and high performance chips are about 80 to 100 W/cm² in the near term. For multiple cost/high performance chips stacked vertically, the package volumetric heat generation rate becomes unacceptably high and needs advanced cooling solutions.

Air cooling has severe limitations in removing heat from closely stacked structures in the 3-D package. One approach to extract heat from a high power density 3-D module is two phase cooling utilizing boiling and condensation. Surface modifications may be used for enhancements of pool boiling from fluid exposed surfaces. However, integration of various components including external pump and tubing, and system miniaturization remains as key challenges.

### SUMMARY OF THE INVENTION

According to a first aspect of the invention, an electronic package is provided which comprises a substrate, a first carrier layer arrangement adapted to dissipate heat from at least one chip mounted thereon, and a heat exchanger mounted on the first carrier layer arrangement. The first carrier layer arrangement comprises at least one microchannel therein, and the microchannel is fluidically connected with the heat exchanger through an inlet and an outlet such that the microchannel is adapted for fluid flow therethrough. The heat exchanger further comprises a pump controlling fluid flow through the microchannel.

Another aspect of the invention relates to a method of assembling an electronic package. At least one chip is mounted on a first carrier layer arrangement, wherein at least one microchannel is produced in the first carrier layer arrangement. The first carrier layer arrangement is attached on a substrate, and the microchannel is fluidically connected with an inlet and an outlet. A heat exchanger is attached on the first carrier layer arrangement and fluidically connected to the inlet and the outlet. The heat exchanger comprises a pump controlling fluid flow through the microchannel, such that the first carrier layer arrangement is adapted to dissipate heat from the chip.

### BRIEF DESCRIPTION OF THE DRAWINGS

In the following description, various embodiments of the invention are described with reference to the following drawings, in which:

FIG. 1 shows the architecture of an electronic package according to one embodiment of the invention.

FIG. 2 shows the architecture of an electronic package according to another embodiment of the invention.

FIG. 3 shows the architecture of an electronic package according to an embodiment of the invention.

FIG. 4 shows a carrier layer according to an embodiment of the invention.

FIG. 5 shows a flowchart of assembling an electronic package according to an embodiment of the invention.

FIG. 6 shows a flowchart of assembling an electronic package according to another embodiment of the invention.

FIG. 7 shows the fabrication process of a carrier layer arrangement according to an embodiment of the invention.

FIG. 8 shows a schematic of fluid flow in the microchannels of the carrier layer arrangement according to an embodiment of the invention.

FIG. 9 shows the simulation results according to the embodiment of the invention.

FIG. 10 shows the simulation results of the effect of flowrate on the power dissipation of the two stacked dies in a package according to an embodiment of the invention.

### DETAILED DESCRIPTION

Embodiments of the present invention provide an electronic package with integrated cooling structure such that fluid circulates within the electronic package.

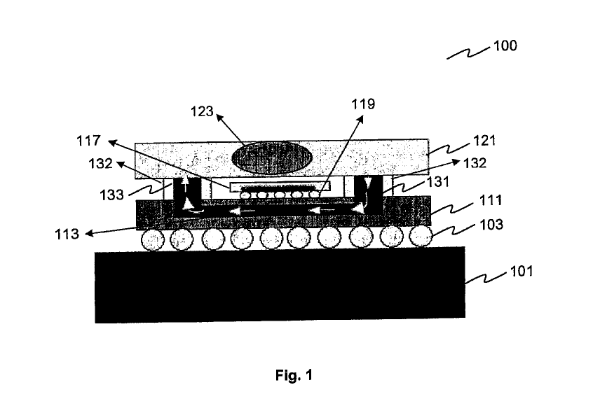

FIG. 1 shows the architecture of an electronic package according to one embodiment of the invention. The electronic package 100 comprises a substrate 101, a first carrier layer arrangement 111 adapted to dissipate heat from at least one chip 117 mounted on the first carrier layer arrangement 111, and a heat exchanger 121 mounted on the first carrier layer arrangement 111. The carrier layer 111 includes at least one microchannel 113 therein, wherein the microchannels 113 are fluidically connected with the heat exchanger 121 through an inlet 131 and an outlet 133 such that the microchannel 113 is adapted for fluid flow therethrough. The heat exchanger 121 further comprises a pump 123 controlling fluid flow through the microchannel 113.

According to an embodiment, the first carrier layer arrangement 111 may be selected to be silicon wafer. The first carrier layer arrangement 111 may be arranged on the substrate using the available attachment technologies, for example using solder balls 103 as shown in FIG. 1.

In an embodiment, the inlet 131 and the outlet 133 may protrude from the surface of the first carrier layer arrangement 111. They may also be buried in the first carrier layer arrangement 111 in another embodiment.

In an embodiment, the electronic package 100 may include at least two interconnects 132 extending upwards from a surface of the first carrier layer arrangement 111, and the inlet 131 and the outlet 133 are comprised in the at least two interconnects 132. According to one embodiment, fluid may flow from the heat exchanger 121 to the microchannels 113, for example, through one interconnect 132 comprising the inlet 131. Fluid in the microchannels 113 may then flow back to the heat exchanger 121, for example, through the other interconnect 132 comprising the outlet 133. The fluid circulating through the carrier layer 111 helps to spread the heat generated by the chip 117, thereby cooling the electronic package 100. In another embodiment, the two interconnects 132 are arranged to hermetically connect the heat exchanger 121 and the first carrier layer arrangement 111. In such a case, fluid would not flow out of the interconnects 132 and the microchannels 113, such that the chip 117 will not be contaminated by the fluid.

It is understood that there may be more than one interconnects from which fluid flow into the microchannels 113, and there may be more than one interconnects from which fluid flow back to the heat exchanger 121. As another example, the more than one interconnects may be fluidically connected with different microchannels, such that more than one fluid circulation path may be formulated. In a further example, one or more of the interconnects may include inlet and/or outlet therein for fluid flow therethrough.

In one embodiment, there may be more than one chips 117 mounted on the first carrier layer arrangement 111, depending on the design of the package. The at least one chip 117 may be housed within the first carrier layer arrangement 111, as shown in FIG. 1. The chips 117 may be integrated circuit in an embodiment. The chips 117 may be attached on the first carrier layer arrangement 111 using the available technologies, such as wire bond, solder attachment and tape. For example in FIG. 1, the chip 117 is attached on the first carrier layer arrangement 111 using solder attachment 119. The chip 117 is electrically connected with the first carrier layer arrangement 111 in one embodiment.

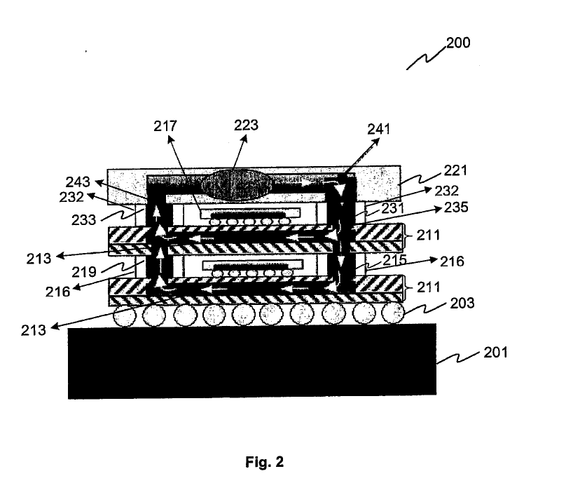

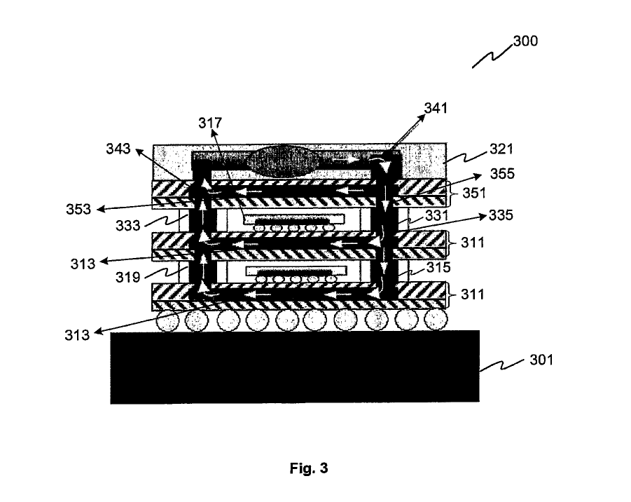

It is in other embodiments that the electronic package may be a 3D package having stacked chips, as will be explained with regard to FIG. 2 and FIG. 3.

As shown in FIG. 2, an electronic package 200 includes a substrate 201, a first and a second carrier layer arrangements 211 arranged on the substrate 201, and a heat exchanger 221 arranged on the second carrier layer arrangement 211. In other embodiments, one or more further carrier layer arrangements may be stacked on the second carrier layer arrangement 211, which are not shown in FIG. 2. At least one chip 217 is mounted on the carrier layer arrangements 211. The carrier layer arrangements 211 include microchannels 213 therein, wherein the microchannels 213 are fluidically connected with the heat exchanger 221 through inlets 231 and outlets 233 such that the microchannels 213 are adapted for fluid flow therethrough. The heat exchanger 221 includes a pump 223 controlling the fluid flow through the microchannels 213.

According to one embodiment, the carrier layer arrangements 211 are stacked vertically in order to, for example, achieve a high-density packaging. The chips 217 mounted on each carrier layer 211 are also stacked vertically in an embodiment.

The electronic package 200 may include interconnects 232 fluidically connecting the heat exchanger 221 and the carrier layer arrangements 211. According to one embodiment, fluid may flow from the heat exchanger 221 to the microchannels 213, for example, through one interconnect 232 comprising the inlet 231. Fluid in the microchannels 213 may then flow back to the heat exchanger 221, for example through the other, interconnect 232 comprising the outlet 233.

In another embodiment, the electronic package 200 includes further interconnects 216 between the adjacent carrier layer arrangements 211, such that fluid flows into the carrier layer 211 through one further interconnect 216 comprising an inlet 215, and flows out of the carrier layer 211 to the other further interconnect 216 comprising an outlet 219. The interconnects 216 may also electrically connect the adjacent carrier layer arrangements 211 in another embodiment.

The further interconnects 216 may have the same structure and material as the interconnects 232 connecting the heat exchanger 221 with the carrier layer arrangement 211. For example, the interconnects 216, 232 may be silicon interconnects providing fluid and electrical connection.

In one embodiment, the carrier layers 211 may include vias for fluidically connecting the microchannels 213 with the inlets 215, 231 and the outlets 219, 233. The carrier layers 211 may also include vias for fluidically and electrically connecting the microchannels 213 with the further interconnects 216 in another embodiment.

As seen from FIG. 2, fluid from the heat exchanger 221 circulates through the respective carrier layer 211 through the interconnects 216, 232 including the respective inlets and outlets. In an illustrative example, cold fluid 241 from the heat exchanger 221 flows into the microchannels 213 of the respective carrier layer arrangement 211. Heat from the chips 217 is transmitted to the microchannels 213, wherein cold fluid may become hot fluid or vapor 243. When the hot fluid or vapor 243 flows back to the heat exchanger 221, heat is dissipated to the ambient through the heat exchanger 221. Thus, the electronic package 200 is able to dissipate the heat generated by the chips 217 in an efficient way.

According to one embodiment, only some of the carrier layers include microchannels therein. In another embodiment, each carrier layer 211 includes microchannels therein, which helps to dissipate heat more efficiently.

In an embodiment, the pump 223 controls the cold fluid 241 flowing into the carrier layer arrangements 211, and controls the hot fluid or vapor 243 flowing back to the heat exchanger 221. In another embodiment, the pump 223 may control the fluid circulation with specific flow rate and pressure head. Various pumping techniques may be used, such as micro pumps and capillary flow. Some examples of miniature pumps include piezoelectric type and MEMS (microelectromechanical system) based pumps.

Another embodiment of the invention is shown in FIG. 3, wherein an electronic package 300 similar to the electronic package 200 is provided.

The electronic package 300 includes a substrate 301, a first and a second carrier layer arrangements 311 arranged on the substrate 301, a third carrier layer arrangement 351 arranged on the second carrier layer arrangement 311, and a heat exchanger 321 arranged on the third carrier layer arrangement 351. More than three carrier layer arrangements may be included in the package 300, wherein only three carrier layer arrangements are shown in the figure. At least one chip 317 is mounted on the first and the second carrier layer arrangements 311. The carrier layer arrangements 311 with the chips 317 are stacked vertically for example. The carrier layer arrangements 311 include microchannels 313 therein, wherein the microchannels 313 are fluidically connected with the heat exchanger 321 for fluid flow through the microchannels 313. The heat exchanger 321 further comprises pumps controlling the fluid flow.

The third carrier layer arrangement 351, in one embodiment, has the same structure and materials as the first and the second carrier layer arrangements 311. In an embodiment, the third carrier layer 351 includes microchannels 353 for fluid circulation therein. The third carrier layer 351 may also include vias 355 for fluidic connection between the heat exchanger 321 and the chip module.

The third carrier layer arrangement 351 is differentiated from the first and the second carrier layer arrangement 311, as there are no chips mounted on the third carrier layer arrangement 351. In other embodiments, the third carrier layer arrangement 351 may also be arranged between the first and the second carrier layer arrangements 311.

In one embodiment, the thickness or height of the carrier layer arrangements 311, 351 is about 1.5 mm. In another embodiment, the distance between the bottom surfaces of adjacent carrier layer arrangements is about 3.0 mm, such that the chip 317 may be arranged inbetween as shown in FIG. 3. The thickness of carrier layer arrangements and the distance between adjacent carrier layer arrangements may be set to other suitable values in other embodiments. The thickness of the carrier layer arrangements may be between about 0.5 mm to about 1.5 mm and the distance between adjacent carrier layer arrangements may be between about 0.4 mm to about 0.7 mm. The dimensions may change depending on the process and design.

In one embodiment, the electronic package 300 may include interconnects 331, 333, 315, 319 fluidically connecting the adjacent carrier layer arrangements 351 and 311. The interconnects 331, 333, 315, 319 may also electrically connect the carrier layer arrangements 311, 351 in another embodiment.

Fluid from the heat exchanger 321 may circulate through the third carrier layer arrangement 351 and the respective carrier layer arrangements 311 by the vias 355 and the interconnects 331, 333, 315, 319. In an illustrative example, cold fluid 341 from the heat exchanger 321 flows into the microchannels 353 of the third carrier layer arrangement 351 and the microchannels 313 of the first and the second carrier layer arrangements 311. Heat from the chips 317 is transmitted to the microchannels 313, wherein cold fluid may become hot fluid or vapor 343. When the hot fluid or vapor 343 flows back to the heat exchanger 321, heat is dissipated to the ambient through the heat exchanger 321. With the third carrier layer 351 which is arranged above the chips 317, heat may be dissipated more efficiently.

The carrier layer arrangements 311 may include vias 335 for fluidically connecting the microchannels 313 with the interconnects 331, 333, 315, 319 in one embodiment. The vias 335 may electrically connecting the microchannels 313 with the interconnects 331, 333, 315, 319 as well, in another embodiment.

The heat exchanger 121, 221, 321 in the above embodiments may be any available heat exchangers which are suitable to be integrated into an electronic package. A heat exchanger is a device built for efficient heat transfer from one fluid to another, whether the fluids are separated by a solid wall or fins so that they do not mix. The solid walls or fins may be designed to have maximum efficiency of heat transfer. In some embodiments of the invention, the heat exchanger may be a liquid to liquid heat exchanger or a liquid to air heat exchanger. In one example, the heat exchanger may include condenser for changing the hot vapor into cold fluid.

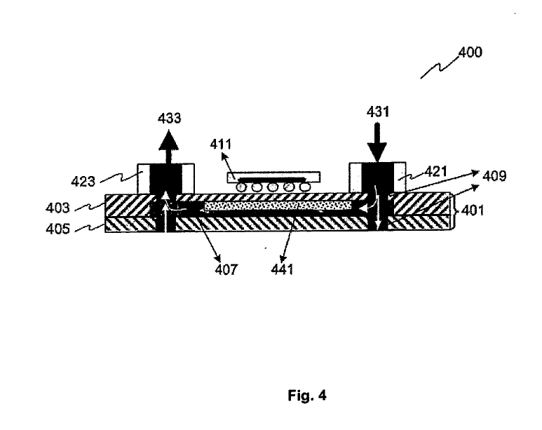

The carrier layer 111, 211, 311, 351 in the above embodiments may have the structure 400 as shown in FIG. 4.

The carrier layer 401 includes microchannels 407 produced therein. In another embodiment, the carrier layer 401 includes vias 409 for fluidic connection with the interconnects 421, 423. At least one chip 411 is electrically connected with the carrier layer 401. Metallization for the chip attachment and electrical connections may be provided on the top and bottom side of the carrier layer 401. For example, metal layers or other electrical conductive layers may be attached on the top and bottom side of the carrier layer 401. The fluidic & electrical interconnections 421, 423 are formed on one side of the carrier layer 401. This arrangement is suitable for stacking multiple carrier layers of a similar configuration. The fluidic & electrical interconnections 421, 423 are attached with the carrier by solder or frid glass or polymer or direct bonding or any other chip to chip/wafer to wafer bonding technique to form hermetic joint.

In one embodiment, the carrier layer 401 includes micro-structures 441 which enhance heat transfer. The micro-structures 441 may be thin structures, which for example transfer heat laterally with an effective thermal spreading resistance. The micro-structures 441 may comprise thermal conductive material, such as metal. For example, aluminum, copper, nickel, magnesium, stainless steel, or any combination thereof may be comprised in the micro-structures 441. In another embodiment, the micro-structures 441 may comprise semiconductor material, such as silicon, germanium, gallium nitride, Silicon on Insulator, indium phosphate, gallium arsenate, or any combination thereof. The micro-structures 441 are deposited inside the microchannels 407 in one embodiment as shown in FIG. 4. The micro-structures 441 may also be deposited outside the microchannels 407 in another embodiment.

In a further embodiment, the carrier layer 401 may comprise a top layer 403 and a bottom layer 405. For example, the vias 409, the microchannels 407 and the micro-structures 441 may be produced in different part of the top layer 403 or bottom layer 405 or both the top layer 403 and the bottom layer 405. The top layer 403 and the bottom layer 405 may then be bonded together.

Heat generated by the chip 411 may be transmitted to the carrier layer 401, and is then transmitted to the heat exchanger through the vias 409, the microchannels 407 and the micro-structures 441. In an illustrative example, cold fluid 431 flows into the microchannels 407, and is heated to become hot fluid or vapor 433 which flows out of the microchannels 407.

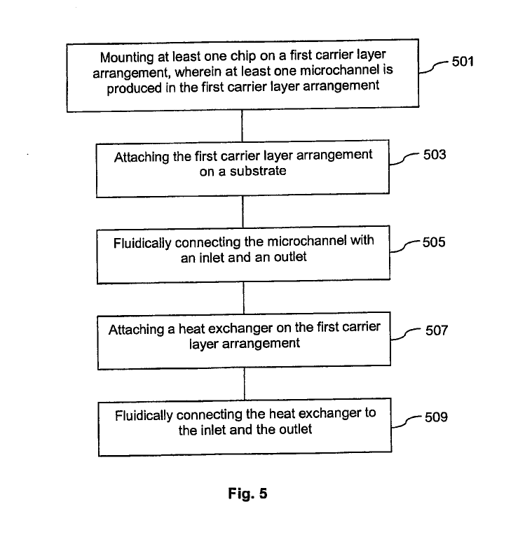

FIG. 5 shows a flowchart of assembling an electronic package according to an embodiment of the invention. At least one chip is mounted on a first carrier layer arrangement at 501, wherein at least one microchannel is produced in the first carrier layer arrangement. The first carrier layer arrangement is attached on a substrate at 503. At 505, the microchannel is fluidically connected with an inlet and an outlet. A heat exchanger is attached on the first carrier layer arrangement at 507. And the heat exchanger is fluidically connected to the inlet and the outlet at 509.

The heat exchanger comprises a pump controlling fluid flow through the microchannel, such that the first carrier layer arrangement is adapted to dissipate heat from the chip.

According to one embodiment, the chip may be attached on the first carrier layer arrangement by solder attachment, wire bond, tape, etc. In an embodiment, the chip is electrically connected with the first carrier layer arrangement. The first carrier layer arrangement may be attached on the substrate through solder ball. Other attachment methods may also be used to attach the first carrier layer arrangement on the substrate.

In an embodiment, at least two interconnects are attached on the first carrier layer arrangement to fluidically connect the microchannels with the heat exchanger. In another embodiment, the two interconnects hermetically connect the heat exchanger and the first carrier layer arrangement such that fluid circulating therein will not contaminate the chip. The interconnects may be attached using, for example, solder attachment, and may be attached using other technique which provides hermetic sealing.

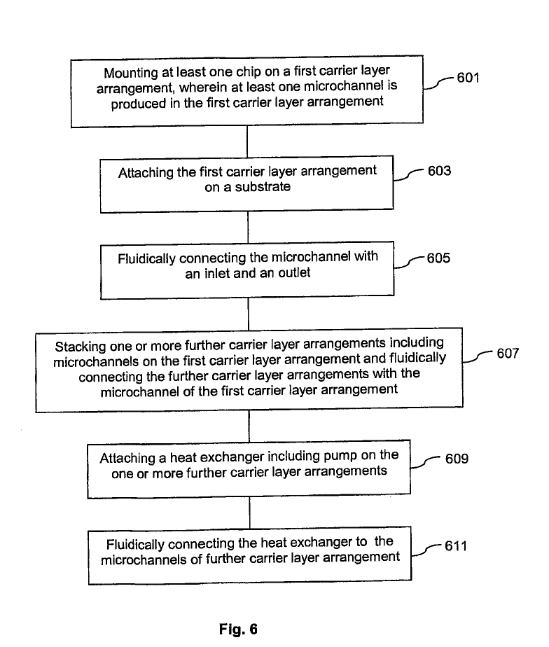

FIG. 6 shows a flowchart of assembling an electronic package according to another embodiment of the invention. At least one chip is mounted on a first carrier layer arrangement at 601, wherein at least one microchannel is produced in the first carrier layer arrangement. The first carrier layer arrangement is attached on a substrate at 603. At 605, the microchannel is fluidically connected with an inlet and an outlet. One or more further carrier layer arrangements including microchannels are stacked on the first carrier layer arrangement and are fluidically connected with the microchannel of the first carrier layer arrangement at 607. A heat exchanger including a pump is attached on the one or more further carrier layer arrangements at 609. And the heat exchanger is fluidically connected to the microchannels of further carrier layer arrangement at 611.

In an embodiment, at least two interconnects are attached on the first carrier layer arrangement to fluidically connect the heat exchanger with the microchannels of the first and the further carrier layer arrangements. Further interconnects may also be attached between the first carrier layer arrangement and the further carrier layer arrangements, and/or between the further carrier layer arrangements. In another embodiment, the interconnects hermetically connect the heat exchanger, the further carrier layer arrangements and the first carrier layer arrangement such that fluid circulating therein will not contaminate the chip.

In another embodiment, before attaching the first carrier layer arrangement and/or the further carrier layer arrangements, heat transfer enhancement micro-structures are etched or attached in the first carrier layer arrangement and/or the further carrier layer arrangements. In one example, micro-structures comprising silicon are etched on the first carrier layer and/or the further carrier layer using silicon machining processes, such as DRIE (deep reactive-ion etching), wet etch, laser machining. In another example, micro-structures comprising other thermal conductive materials may be attached in the first and/or the further carrier layer arrangements using, e.g. solder.

According to an embodiment, the first carrier layer arrangement or the further carrier layer arrangements are wafer, which may comprise a top layer and a bottom layer. The top layer and the bottom layer are bonded together to form each carrier layer arrangement. In another embodiment, electrically conductive material, such as metal layer, may be deposited on the top and the bottom surface of the carrier layer arrangements such that the carrier layers are electrically connected with the respective chips mounted thereon.

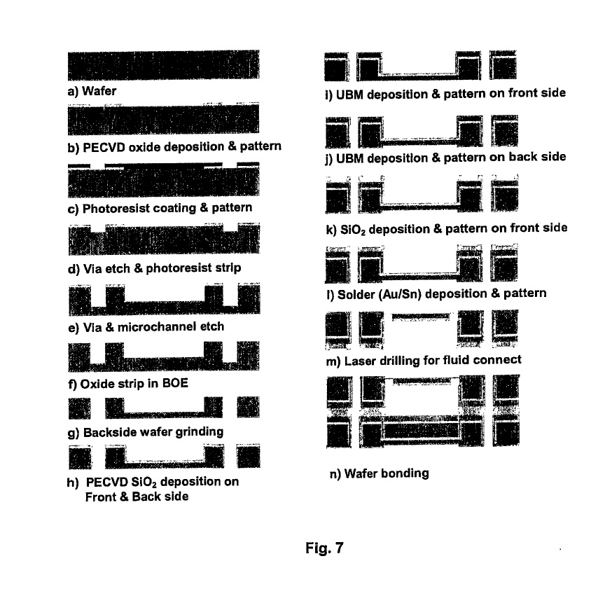

FIG. 7 shows the fabrication process of a carrier layer arrangement according to an embodiment of the invention. The process starts with a wafer in FIG. 7a). 3 μm PECVD (Plasma Enhanced Chemical Vapor Deposition) oxide deposition and pattern is performed in FIG. 7b). In FIG. 7c), photoresist coating and pattern is performed. Vias are then etched, e.g. with about 100 um and photoresist is stripped in FIG. 7d). Vias and microchannel are then etched, e.g. with about 400 um in FIG. 7e). Oxide strip process is performed in a buffered oxide etchant (BOE) solution in FIG. 7f). The backside wafer is ground, e.g. to about 500 um in FIG. 7g). In FIG. 7h), about 1 um PECVD SiO₂ deposition is carried out on the front and the back side. In FIG. 7i) UBM (under bump metallurgy) deposition and pattern are performed on the front side, and UBM deposition and pattern are performed on the back side in FIG. 7j). SiO₂ deposition and pattern are preformed on the front side in FIG. 7k). Solder (Au/Sn) deposition and pattern are performed in FIG. 7l). Laser drilling is performed for fluid connection in FIG. 7m). Finally, wafer bonding is carried out in FIG. 7n).

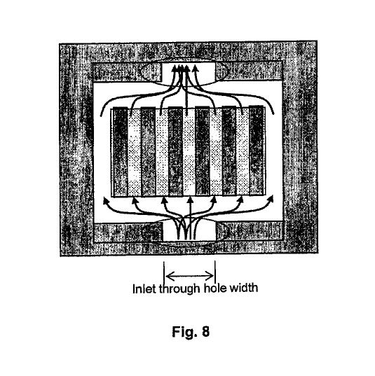

FIG. 8 shows a schematic of fluid flow in the microchannels of the carrier layer arrangement according to an embodiment of the invention. In this example, a plurality of microchannels are included in the carrier layer arrangement.

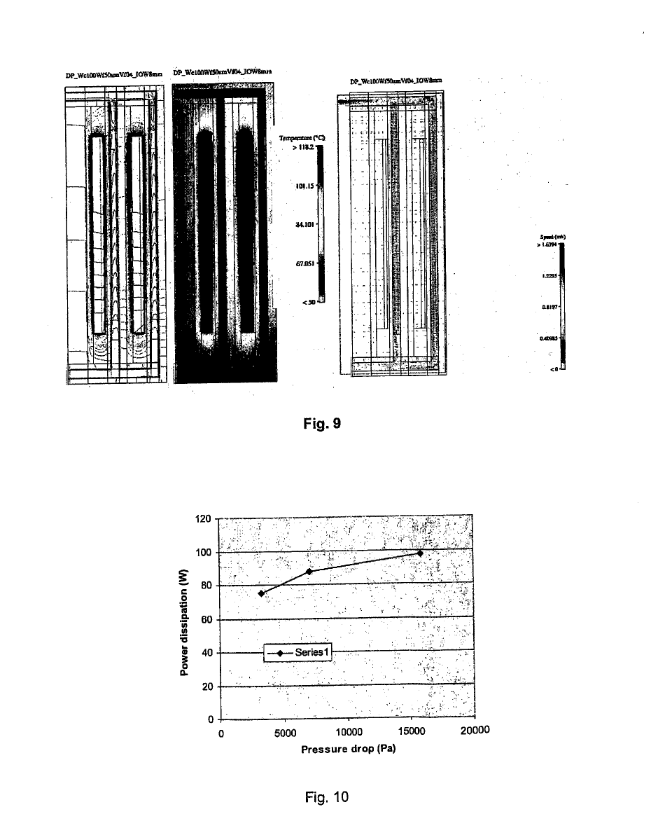

FIG. 9 shows the simulation results (temperature isothermal line, contour and velocity vector map) at the symmetry plane at 0.4 lpm. FIG. 10 shows the effect of flow rate on the power dissipation of the two stacked dies in the package.

The embodiments of the invention provides primary fluid circulation within the electronic (3D) package, thereby achieving less system level design complexity. With the efficient heat dissipation of the electronic package, high power dissipating integrated circuits can be stacked into the electronic package, which further enhances miniaturization and reduces interconnect distances

Whilst the present invention has been described with reference to preferred embodiments it should be appreciated that modifications and improvements may be made to the invention without departing from the spirit and scope of the invention as defined in the following claims.

1. An electronic package comprising:
a substrate;
a first carrier layer arrangement adapted to dissipate heat from at least one chip mounted thereon, and
a heat exchanger mounted on the first carrier layer arrangement,
wherein the first carrier layer arrangement comprises at least one microchannel therein, the microchannel being fluidically connected with the heat exchanger through an inlet and an outlet such that the microchannel is adapted for fluid flow therethrough,
wherein the heat exchanger further comprises a pump controlling fluid flow through the microchannel.

2. The electronic package of claim 1, wherein the first carrier layer arrangement further comprises at least one via for fluidically connecting the microchannels with the inlet and the outlet.

3. The electronic package of claim 1, wherein the first carrier layer arrangement further comprises at least two interconnects extending upwards from a surface of the first carrier layer arrangement, and the at least two interconnects comprises the inlet and the outlet.

4. The electronic package of claim 3, wherein the interconnects hermetically connect the first carrier layer arrangement with the heat exchanger.

5. The electronic package of claim 1, wherein the at least one chip is housed within the first carrier layer arrangement.

6. The electronic package of claim 1, wherein the at least one chip is electrically connected with the first carrier layer arrangement.

7. The electronic package of claim 1, wherein the at least one chip is an integrated circuit.

8. The electronic package of claim 1, further comprising a second carrier layer arrangement arranged between the first carrier layer arrangement and the heat exchanger, the second carrier layer arrangement comprising at least one microchannel therein.

9. The electronic package of claim 8, wherein the second carrier layer arrangement is fluidically and electrically connected with the first carrier layer arrangement.

10. The electronic package of claim 8, further comprising one or more carrier layer arrangements arranged between the second carrier layer arrangement and the heat exchanger, the one or more carrier layer arrangements being fluidically and electrically connected with the first and the second carrier layer arrangements.

11. The electronic package of claim 1, wherein the carrier layer arrangement further comprises micro-structures for heat transfer.

12. The electronic package of claim 11, wherein the micro-structures comprise metal or semiconductor material.

13. The electronic package of claim 12, wherein the micro-structures comprise aluminum, copper, nickel, magnesium, stainless steel, or any combination thereof.

14. The electronic package of claim 12, wherein the micro-structures comprise silicon, germanium, gallium nitride, Silicon-on-Insulator, indium phosphate, gallium arsenate, or any combination thereof.

15. The electronic package of claim 1, wherein the carrier layer arrangement comprises a top layer and a bottom layer.

16. The electronic package of claim 15, wherein the at least one microchannel is comprised in the top layer, the bottom layer or both the top and bottom layer.

17. The electronic package of claim 1, wherein the heat exchanger is a liquid to liquid heat exchanger or a liquid to air heat exchanger.

18. The electronic package of claim 1, wherein the pump is selected to be piezoelectric pump or microelectromechanical system based pump.

19. A method of assembling an electronic package, comprising
mounting at least one chip on a first carrier layer arrangement, wherein at least one microchannel is produced in the first carrier layer arrangement, and
attaching the first carrier layer arrangement on a substrate,
fluidically connecting the microchannel with an inlet and an outlet,
attaching a heat exchanger on the first carrier layer arrangement,
fluidically connecting the heat exchange to the inlet and the outlet,
wherein the heat exchanger comprises a pump controlling fluid flow through the microchannel, such that the first carrier layer arrangement is adapted to dissipate heat from the chip.

20. The method of claim 19, further comprising attaching at least two interconnects on the first carrier layer arrangement, the two interconnects being extending upwards from a surface of the first carrier layer arrangement and comprising the inlet and the outlet.

21-27. (canceled)
